(19) United States
(12) Patent Application Publication
(10) Pub. No.: US 2007/0045864 A1
(43) Pub. Date: Mar. 1, 2007

(54) Semiconductor device including a plurality of semiconductor chips stacked three-dimensionally, and method of manufacturing the same

(76) Inventors: Hiroshi Shiba, Fujisawa-shi (JP); Makoto Segawa, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/503,129

(22) Filed: Aug. 14, 2006

(30) Foreign Application Priority Data
Aug. 23, 2005 (JP) 2005-241427

(51) Int. Cl. H01L 23/52

(52) U.S. Cl. 257/777

(57) ABSTRACT

A semiconductor device includes a package substrate having a chip mounting surface with at least a plurality of first substrate-side pads and a plurality of second substrate-side pads, a rectangular first semiconductor chip having a first main surface fixed on the chip mounting surface, a plurality of first bonding wires through which a plurality of first pads arranged along one side of a second main surface of the first semiconductor chip and the first substrate-side pads are bonded to each other, a rectangular second semiconductor chip having a third main surface fixed on the second main surface, and a plurality of second bonding wires through which a plurality of second pads arranged along one side of a fourth main surface of the second semiconductor chip and the second substrate-side pads are bonded to each other.

### CROSS-REFERENCE TO RELATED APPLICATIONS

This application is based upon and claims the benefit of priority from prior Japanese Patent Application No. 2005-241427, filed Aug. 23, 2005, the entire contents of which are incorporated herein by reference.

### BACKGROUND OF THE INVENTION

1. Field of the Invention

The present invention relates to a semiconductor device and a method of manufacturing the semiconductor device. More specifically, the invention relates to a multichip package (MCP) including a plurality of semiconductor chips stacked three-dimensionally and a method of manufacturing the MCP.

2. Description of the Related Art

Attention has recently been attracted to an MCP including a plurality of semiconductor chips stacked three-dimensionally as semiconductor devices are required to increase in packaging density and function. In the MCP, there has been known a method of mounting a first chip on a mounting substrate and then mounting a second chip on the first chip with an intermediate substrate therebetween (see, for example, Jpn. Pat. Appln. KOKAI Publication No. 2004-71997). In this method, the pads of the first and second chips are electrically bonded to the electrodes on the mounting substrate through bonding wires.

When the pads of a plurality of chips stacked three-dimensionally are bonded through their respective bonding wires, an intermediate substrate or a dummy chip has to be interposed between adjacent chips in order to keep the level of a loop of each of the bonding wires. For example, in order to stack four chips of the same shape, the four chips and three intermediate substrates or dummy chips have to be mounted on a mounting substrate, thus causing the problem that an MCP is difficult to miniaturize and thin.

### BRIEF SUMMARY OF THE INVENTION

According to a first aspect of the present invention, there is provided a semiconductor device comprising a package substrate having a chip mounting surface and an external connecting surface opposed to the chip mounting surface, the chip mounting surface including at least a plurality of first substrate-side pads and a plurality of second substrate-side pads; a rectangular first semiconductor chip having a first main surface fixed on the chip mounting surface and a second main surface opposed to the first main surface, the first semiconductor chip including a plurality of first pads arranged along one side of the second main surface; a plurality of first bonding wires through which the first pads and the first substrate-side pads are bonded to each other; a rectangular second semiconductor chip having a third main surface fixed on the second main surface and a fourth main surface opposed to the third main surface, the second semiconductor chip including a plurality of second pads arranged along one side of the fourth main surface and being displaced from above the first semiconductor chip to prevent the second pads from being arranged right above the first pads; and a plurality of second bonding wires through which the second pads and the second substrate-side pads are bonded to each other.

According to a second aspect of the present invention, there is provided a method of manufacturing a semiconductor device, comprising fixing a first main surface of a rectangular first semiconductor chip on a chip mounting surface of a package substrate, the package substrate having an external connecting surface opposed to the chip mounting surface, the chip mounting surface including at least a plurality of first substrate-side pads and a plurality of second substrate-side pads, the first semiconductor chip having a second main surface opposed to the first main surface and including a plurality of first pads arranged along one side of the second main surface; fixing a third main surface of a second semiconductor chip on the second main surface of the first semiconductor chip, the second semiconductor chip having a fourth main surface opposed to the third main surface and including a plurality of second pads arranged along one side of the fourth main surface, the second semiconductor chip being displaced from above the first semiconductor chip to prevent the second pads from being arranged right above the first pads; bonding the first pads and the first substrate-side pads to each other through first bonding wires; and bonding the second pads and the second substrate-side pads to each other through second bonding wires.

### BRIEF DESCRIPTION OF THE SEVERAL VIEWS OF THE DRAWING

FIG. 1 is a sectional view showing a configuration of a semiconductor device according to a first embodiment of the present invention;

FIG. 2 is a plan view of the configuration of the semiconductor device according to the first embodiment;

FIG. 3 is a sectional view illustrating a method of manufacturing the semiconductor device according to the first embodiment;

FIG. 4 is a sectional view illustrating the method of manufacturing the semiconductor device according to the first embodiment;

FIG. 5 is a sectional view illustrating the method of manufacturing the semiconductor device according to the first embodiment;

FIG. 6 is a sectional view illustrating the method of manufacturing the semiconductor device according to the first embodiment;

FIG. 7 is a sectional view illustrating the method of manufacturing the semiconductor device according to the first embodiment;

FIG. 8 is a sectional view illustrating the method of manufacturing the semiconductor device according to the first embodiment;

FIG. 9 is a sectional view illustrating the method of manufacturing the semiconductor device according to the first embodiment;

FIG. 10 is a plan view showing a configuration of a semiconductor device according to a modification to the first embodiment;

FIG. 11 is a sectional view showing a configuration of a semiconductor device according to a second embodiment of the present invention;

FIG. 12 is a plan view of the configuration of the semiconductor device according to the second embodiment of the present invention;

FIG. 13 is a sectional view illustrating a method of manufacturing the semiconductor device according to the second embodiment;

FIG. 14 is a sectional view illustrating the method of manufacturing the semiconductor device according to the second embodiment;

FIG. 15 is a sectional view illustrating the method of manufacturing the semiconductor device according to the second embodiment;

FIG. 16 is a sectional view illustrating the method of manufacturing the semiconductor device according to the second embodiment;

FIG. 17 is a sectional view illustrating the method of manufacturing the semiconductor device according to the second embodiment; and

FIG. 18 is a sectional view illustrating the method of manufacturing the semiconductor device according to the second embodiment;

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### First Embodiment

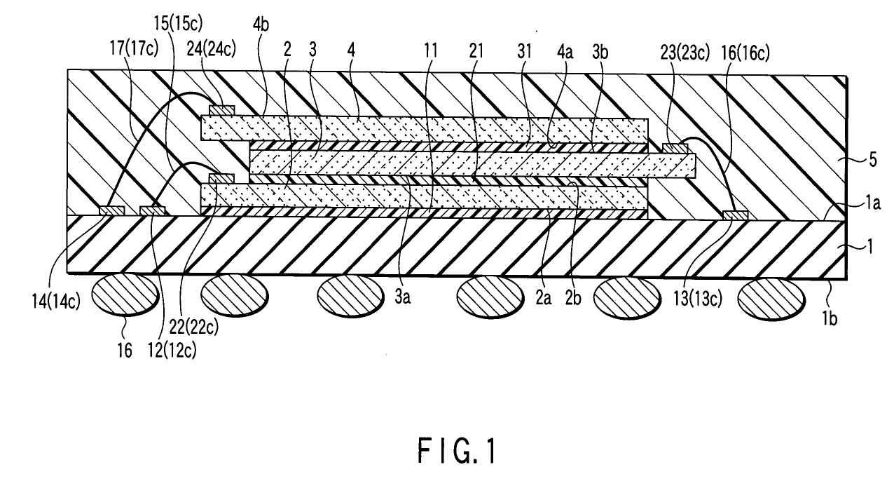

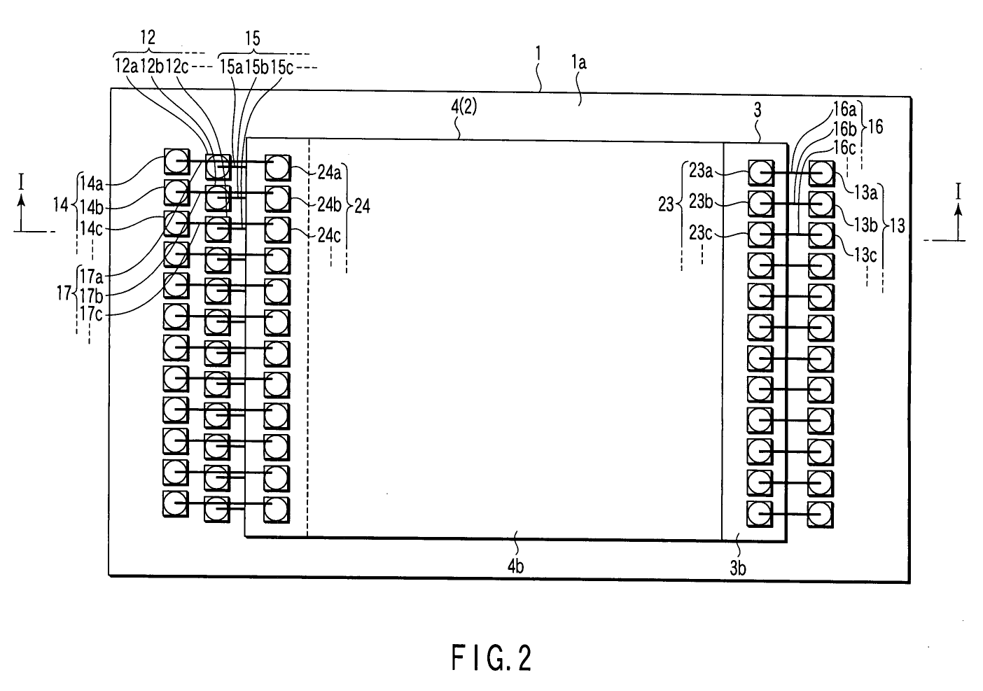

FIGS. 1 and 2 show a configuration of a semiconductor device according to a first embodiment of the present invention. The semiconductor device is directed to a multichip package (MCP) including three semiconductor chips that are stacked three-dimensionally. FIG. 1 is a sectional view of the semiconductor device, and FIG. 2 is a plan view thereof, which is viewed from the sixth main surface of a third semiconductor chip. The sectional view of FIG. 1 is taken along line I-I of FIG. 2.

Referring to FIG. 1, the semiconductor device is so configured that at least first, second and third semiconductor chips 2, 3 and 4 of the same shape are stacked three-dimensionally on a package substrate 1. The package substrate 1 has a chip mounting surface la and an external connecting surface 1b opposed to the surface la. First, second and third substrate-side pads 12 (12c), 13 (13c) and 14 (14c) are arranged on the chip mounting surface la. The first semiconductor chip 2 is rectangular and has a first main surface 2a fixed on the chip mounting surface la and a second main surface 2b opposed to the first main surface 2a. First pads 22 (22c) are arranged along one side of the second main surface 2b. The first semiconductor chip 2 is fixed on the package substrate 1 such that the first pads 22 (22c) are close to the first substrate-side pads 12 (12c). The first pads 22 (22c) of the first semiconductor chip 2 and the first substrate-side pads 12 (12c) are bonded to each other through first bonding wires 15 (15c).

The second semiconductor chip 3 is rectangular and includes a third main surface 3a fixed on the second main surface 2b of the first semiconductor chip 2 and a fourth main surface 3b opposed to the third main surface 3a. The chip 3 includes second pads 23 (23c) along one side of the fourth main surface 3b. The second pads 23 (23c) are arranged close to the second substrate-side pads 13 (13c). The chip 3 is displaced from right above the first semiconductor chip 2 only by a region corresponding to at least the second pads 23 (23c) so as to prevent the second pads 23 (23c) from being formed right above the first pads 22 (22c). The second pads 23 (23c) of the second semiconductor chip 3 and the second substrate-side pads 13 (13c) are bonded to each other through second bonding wires 16 (16c).

The third semiconductor chip 4 is rectangular and includes a fifth main surface 4a fixed on the fourth main surface 3b of the second semiconductor chip 3 and a sixth main surface 4b opposed to the fifth main surface 4a. The chip 4 includes third pads 24 (24c) along one side of the sixth main surface 4b. The third pads 24 (24c) are arranged close to the third substrate-side pads 14 (14c). The chip 4 is displaced from right above the second semiconductor chip 3 only by a region corresponding to at least the third pads 24 (24c) to prevent the third pads 24 (24c) from being formed right above the second pads 23 (23c). The chip 4 overlaps the first semiconductor chip 2 two-dimensionally as shown in FIG. 2. The third pads 24 (24c) of the third semiconductor chip 4 and the third substrate-side pads 14 (14c) are bonded to each other through third bonding wires 17 (17c).

The package substrate 1 can be made of various types of organic resin, ceramic, and inorganic materials such as glass. The inorganic resin includes phenol resin, polyester resin, epoxy resin, polyimide resin and fluorocarbon resin. The package substrate 1 has base materials such as paper, cloth and glass, which are used when the substrate 1 is formed like a plate. The package substrate 1 can be replaced with a lead frame that is formed by stacking high heat-resistant polyimide resin plates on metal such as copper (Cu). The package substrate 1 can also be replaced with a buildup multilayer wiring plate. The chip mounting surface la of the package substrate 1 is defined as a surface on which the first, second and third semiconductor chips 2, 3 and 4 are mounted. The chip mounting surface la can be coated with a protection film (passivation film). The package substrate 1 includes a plurality of wiring layers and vias for bonding the wiring layers (none of which are shown).

As shown in FIG. 2, the first, second and third substrate-side pads 12 (12a, 12b, 12c, . . . ), 13 (13a, 13b, 13c, . . . ) and 14 (14a, 14b, 14c, . . . ) are arranged in line on the chip mounting surface la of the package substrate 1. The first and third substrate-side pads 12 and 14 are arranged close to each other. The second substrate-side pads 13 are arranged at a sufficient distance from the first substrate-side pads 12 to mount the first, second and third semiconductor chips 2, 3 and 4.

The first substrate-side pads 12 (12a, 12b, 12c, . . . ) are electrically bonded to the first pads 22 (22a, 22b, 22c, . . . ) (not seen from the plan view of FIG. 2) of the first semiconductor chip 2 through the first bonding wires 15 (15a, 15b, 15c, . . . ), respectively. Particularly in the semiconductor device shown in FIGS. 1 and 2, the positions of the first pads 22 (22a, 22b, 22c, . . . ) are almost equal to those of the third pads 24 (24a, 24b, 24c, . . . ), and the number of the first pads 22 is the same as that of the third pads 24.

The second substrate-side pads 13 (13a, 13b, 13c, . . . ) are electrically bonded to the second pads 23 (23a, 23b, 23c, . . . ) through the second bonding wires 16 (16a, 16b, 16c, . . . ). The second pads 23 are arranged in line along one side of the second semiconductor chip 3.

The third substrate-side pads 14 (14a, 14b, 14c, . . . ) are electrically bonded to the third pads 24 (24a, 24b, 24c, . . . ) through the third bonding wires 17 (17a, 17b, 17c, . . . ). The third pads 24 are arranged in line along one side of the third semiconductor chip 4.

The first, second and third substrate-side pads 12, 13 and 14 shown in FIGS. 1 and 2 are connected to a plurality of external connecting terminals 6 arranged on the external connecting surface 1b of the package substrate 1 through wires (not shown) formed inside the package substrate 1. The external connecting terminals 6 are used to connect the package substrate 1 to a mounting substrate (board) and the like. The external connecting terminals 6 can be formed of not only eutectic solder but also solder materials using no lead, such as tin-silver (Sn—Ag).

First, second and third fixing resin layers 11, 21 and 31 are formed to fix the first, second and third semiconductor chips 2, 3 and 4, and their shapes almost correspond to the outside shapes of the first, second and third semiconductor chips 2, 3 and 4. Favorably, the first, second and third fixing resin layers 11, 21 and 31 are made of organic synthetic resin of epoxy type or acrylic type. The synthetic resin includes liquid resin and sheet (film) resin. The sheet resin is easier to handle and its thickness is also easier to control than the liquid resin. If the sheet resin is used in the semiconductor device shown in FIG. 1, the device can easily be thinned.

The first, second and third semiconductor chips 2, 3 and 4 are of the same shape. A sealing resin layer 5 is formed around the first, second and third semiconductor chips 2, 3 and 4. The sealing resin layer 5 can be made of organic synthetic resin of epoxy type or acrylic type. It is favorable that the first, second and third fixing resin layers 11, 21 and 31 and the sealing resin layer 5 be made of the same material in view of a decrease in reliability due to peeling or the strength of bonding at an interface.

According to the semiconductor device shown in FIG. 1, the second semiconductor chip 3 is mounted on the first semiconductor chip 2. The first semiconductor chip 2 has the first pads 22 formed along one side thereof to define the outer shape thereof. The first and second semiconductor chips 2 and 3 of the same shape. The second semiconductor chip 3 is displaced from right above the first semiconductor chip 2 only by a region corresponding to the second pads 23 to prevent the second pads 23 from being formed right above the first pads 22. A region corresponding to the height of a loop of the first bonding wires 15 required when the first pads 22 and the first substrate-side pads 12 are bonded through the first bonding wires 15 can easily be secured by the second semiconductor chip 3. An intermediate substrate or a dummy chip need not be arranged on the first semiconductor chip 2; accordingly, the semiconductor device can be thinned.

The third semiconductor chip 4 is displaced from right above the second semiconductor chip 3 only by a region corresponding to the third pads 24 to prevent the third pads 14 from being formed right above the second pads 23. A region corresponding to the height of a loop of the second bonding wires 16 required when the second pads 23 and the second substrate-side pads 13 are bonded through the second bonding wires 16 can easily be secured by the third semiconductor chip 4. Accordingly, the semiconductor device can be thinned.

In order to mount another semiconductor chip on the third semiconductor chip 4 further, it has only to be displaced from right above the third semiconductor chip 4 only by a region corresponding to the pads of the chip 4 so as to overlap the second semiconductor chip 3.

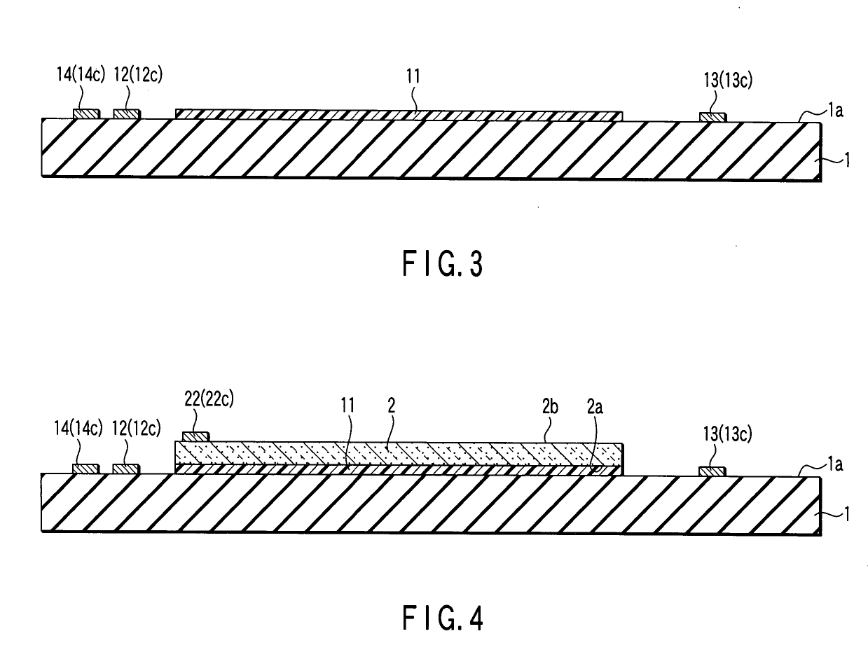

A method of manufacturing the semiconductor device according to the first embodiment will be described with reference to FIGS. 3 to 9.

Referring first to FIG. 3, a package substrate 1 having first, second and third substrate-side pads 12 (12c), 13 (13c) and 14 (14c) on the chip mounting surface la thereof is prepared. A first fixing resin layer 11 is formed on the chip mounting surface la of the package substrate 1. The first fixing resin layer 11 is shaped like a sheet in advance such that its shape almost corresponds to the outer shape of the first semiconductor chip 2, and it can be adhered directly onto the chip 2. The first fixing resin layer 11 can be formed by forming a resin layer on the chip mounting surface la and selectively punching the resin layer.

Then, a rectangular first semiconductor chip 2 having a first main surface 2a and a second main surface 2b opposed to the first main surface 2a is prepared. On the second main surface 2a, as shown in FIG. 2, first pads 22 (22a, 22b, 22c, . . . ) are arranged in line along one side of the first semiconductor chip 2. The first main surface 2a of the first semiconductor chip 2 is fixed on the first fixing resin layer 11 as shown in FIG. 4.

Referring then to FIG. 5, one end of the first bonding wire 15 (15c) is bonded to the first substrate-side pad 12 (12c), and the other end thereof is bonded to the first pad 22 (22c) by thermocompression bonding or ultrasonic bonding. Since the first bonding wires 15 (15c) are lifted from the first substrate-side pads 12 (12c) on the package substrate 1 and bonded to the first pads 22 (22c), the level of a loop of the first bonding wires 15 (15c) can be lowered and the semiconductor device can easily be thinned. Moreover, a sheet-shaped second fixing resin layer 21 is formed on the second main surface 2b.

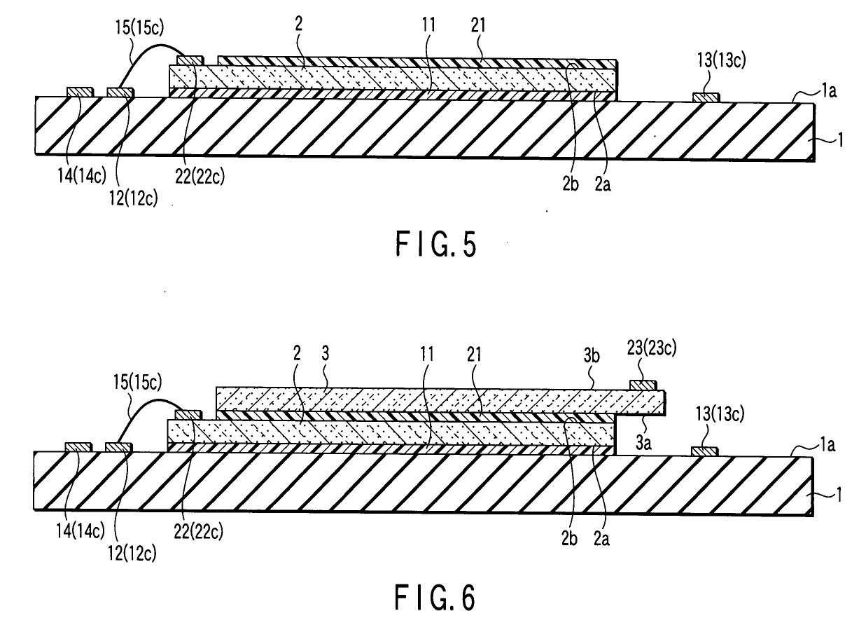

Then, a rectangular second semiconductor chip 3 having a third main surface 3a and a fourth main surface 3b opposed to the third main surface 3a is prepared. On the fourth main surface 3b, as shown in FIG. 2, second pads 23 (23a, 23b, 23c, . . . ) are arranged in line along one side of the second semiconductor chip 3. As shown in FIG. 6, the second semiconductor chip 3 is displaced from right above the first semiconductor chip 2 only by a region where the second pads 23 (23a, 23b, 23c, . . . ) are formed, and the third main surface 3a of the second semiconductor chip 3 is fixed on the second fixing resin layer 21.

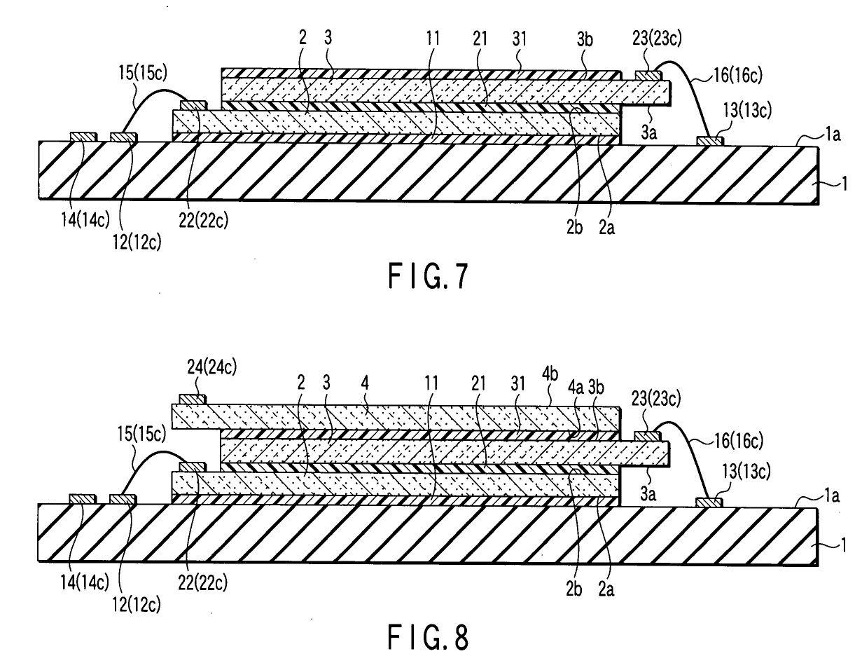

Referring then to FIG. 7, one end of the second bonding wire 16 (16c) is bonded to the second substrate-side pad 13 (13c), and the other end thereof is bonded to the second pad 23 (23c) by thermocompression bonding or ultrasonic bonding. A sheet-shaped third fixing resin layer 31 is formed on the fourth main surface 3b.

Then, a rectangular third semiconductor chip 4 having a fifth main surface 4a and a sixth main surface 4b opposed to the fifth main surface 4a is prepared. On the sixth main surface 4b, as shown in FIG. 2, third pads 24 (24a, 24b, 24c, . . . ) are arranged in line along one side of the third semiconductor chip 4. As shown in FIG. 8, the third semiconductor chip 4 is displaced from right above the second semiconductor chip 3 only by a region where the third pads 24 (24a, 24b, 24c, . . . ) are formed, and the fifth main surface 4a of the third semiconductor chip 4 is fixed on the third fixing resin layer 31.

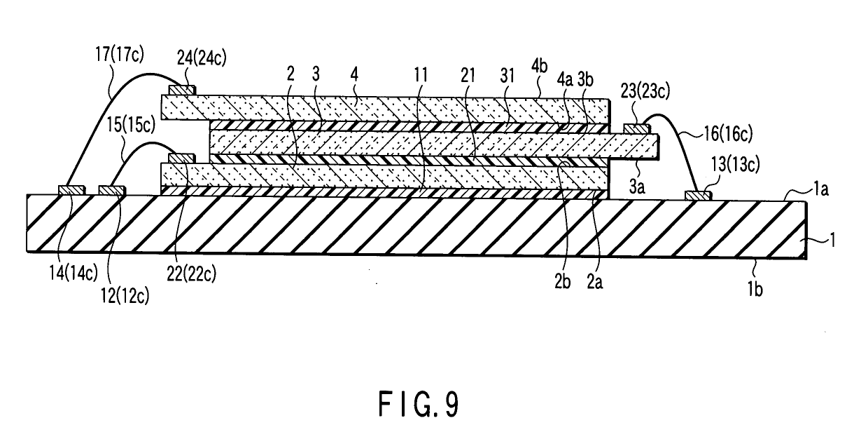

Referring then to FIG. 9, one end of the third bonding wire 17 (17c) is bonded to the third substrate-side pad 14 (14c), and the other end thereof is bonded to the third pad 24 (24c) by thermocompression bonding or ultrasonic bonding.

Finally, a sealing resin layer 5 is formed around the first, second and third semiconductor chips 2, 3 and 4, and an external connecting terminal 6 is provided on the external connecting surface 1b of the package substrate 1. Thus, the semiconductor device shown in FIGS. 1 and 2 is completed.

In the method of manufacturing the semiconductor device according to the first embodiment, a second semiconductor chip 3 having the second pads 23 (23a, 23b, 23c, . . . ), which are formed along one side of the chip 3 to define the outer shape thereof, is prepared. As shown in FIG. 2, the second semiconductor chip 3 is displaced from right above the first pads 22 (22a, 22b, 22c, . . . ) only by a region where the second pads 23 (23a, 23b, 23c, . . . ) are formed, and formed on the first semiconductor chip 2. A third semiconductor chip 4 having the third pads 24 (24a, 24b, 24c, . . . ), which are formed along one side of the chip 4 to define the outer shape thereof, is prepared. The third semiconductor chip 4 is displaced from right above the second pads 23 (23a, 23b, 23c, . . . ) only by a region where the third pads 24 (24a, 24b, 24c, . . . ) are formed, and formed on the second semiconductor chip 3. Thus, an intermediate substrate or a dummy chip need not be inserted between the first and second semiconductor chips 2 and 3 or between the second and third semiconductor chips 3 and 4. The second semiconductor chip 3 can keep space for arranging the second bonding wires 16 and the third semiconductor chip 4 can keep space for arranging the third bonding wires 17. The semiconductor device can thus be thinned. The first, second and third bonding wires 15, 16 and 17 extend from the package substrate 1 toward the first, second and third semiconductor chips 2, 3 and 4. As compared with the case where the bonding wires 15, 16b and 17 extend from the semiconductor chips 2, 3 and 4 toward the package substrate 1, the level of a loop of the first, second and third bonding wires 15, 16 and 17 can be lowered. Accordingly, the semiconductor device can be more thinned.

[Modification]

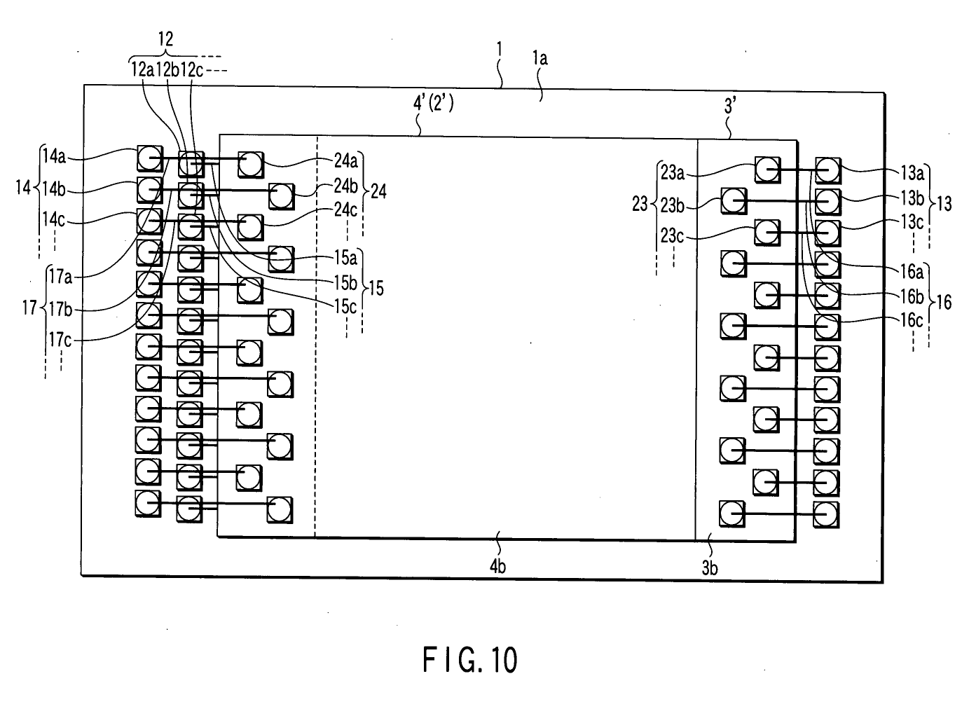

FIG. 10 is a plan view showing a modification to the semiconductor device according to the first embodiment of the present invention. The same components as those of the semiconductor device (shown in, e.g., FIG. 2) are denoted by the same reference numerals and their detailed descriptions are omitted.

Referring to FIG. 10, the second pads 23 (23a, 23b, 23c, . . . ) of a second semiconductor chip 3′ are arranged in two lines in a staggered fashion along one side of the chip 3′. Similarly, the third pads 24 (24a, 24b, 24c, . . . ) of a second semiconductor chip 4′ are arranged in two lines in a staggered fashion along one side of the chip 4′. Though not seen from the plan view of FIG. 10, the first pads 22 of a first semiconductor chip 2′ as well as the third pads 24 are arranged in two lines in a staggered fashion along one side of the chip 2′. In this respect, the semiconductor device shown in FIG. 10 widely differs from that shown in FIG. 2.

The semiconductor device shown in FIG. 10 can also be thinned because the first, second and third pads 22, 23 and 24 on the first, second and third semiconductor chips 2′, 3′ and 4′ and the first, second and third substrate-side pads 12, 13 and 14 on the package substrate 1 can electrically be connected to each other without arranging any intermediate substrate or dummy chip between the first, second and third semiconductor chips 2′, 3′ and 4′.

### Second Embodiment

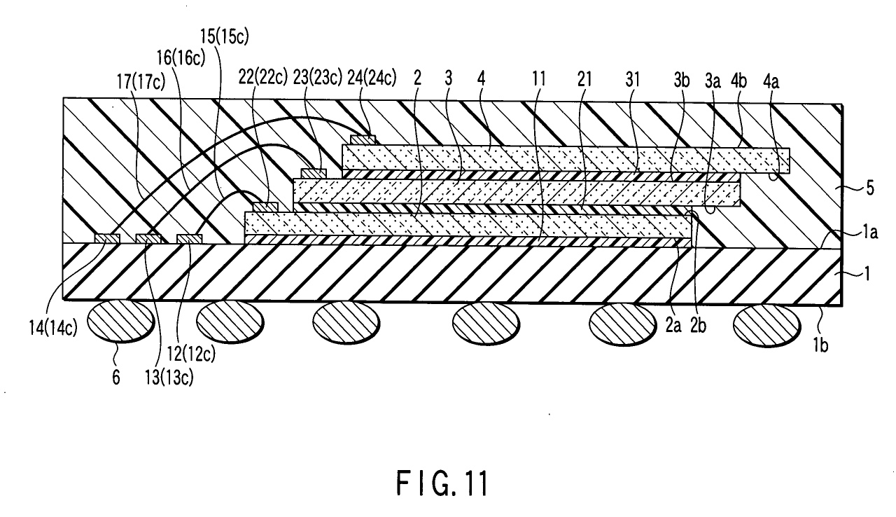

FIG. 11 shows a semiconductor device according to a second embodiment of the present invention. The same components as those of the semiconductor device (shown in, e.g., FIG. 1) are denoted by the same reference numerals and their detailed descriptions are omitted.

Referring to FIG. 11, the semiconductor device is so configured that at least first, second and third semiconductor chips 2, 3 and 4 of the same shape are stacked three-dimensionally on a package substrate 1. The package substrate 1 has a chip mounting surface la and an external connecting surface 1b opposed to the surface 1a. First, second and third substrate-side pads 12 (12c), 13 (13c) and 14 (14c) are arranged on the chip mounting surface 1a. The first, second and third substrate-side pads 12 (12c), 13 (13c) and 14 (14c) are arranged close to each other. In this respect, the semiconductor device of the second embodiment widely differs from that of the first embodiment shown in FIG. 1. Furthermore, a first fixing resin layer 11 is formed on the chip mounting surface la of the package substrate 1.

The first semiconductor chip 2 is rectangular and has a first main surface 2a fixed on the chip mounting surface 1a and a second main surface 2b opposed to the first main surface 2a. First pads 22 (22c) are arranged along one side of the second main surface 2b. The first semiconductor chip 2 is fixed on the package substrate 1 such that the first pads 22 (22c) are close to the first substrate-side pads 12 (12c). The first pads 22 (22c) of the first semiconductor chip 2 and the first substrate-side pads 12 (12c) are bonded to each other through first bonding wires 15 (15c). Furthermore, a second fixing resin layer 21 is formed on the second main surface 2b of the first semiconductor chip 2.

The second semiconductor chip 3 is rectangular and includes a third main surface 3a fixed on the second main surface 2b of the first semiconductor chip 2 and a fourth main surface 3b opposed to the third main surface 3a. The chip 3 includes second pads 23 (23c) along one side of the fourth main surface 3b. The chip 3 is displaced from right above the first semiconductor chip 2 only by a region corresponding to at least the first pads 22 (22c) such that the first pads 22 (22c) are prevented from being formed right above the first pads 22 (22c) but they are adjacent to the first pads 22 (22c). The second pads 23 (23c) of the second semiconductor chip 3 and the second substrate-side pads 13 (13c) are bonded to each other through second bonding wires 16 (16c). Furthermore, a third fixing resin layer 31 is formed on the fourth main surface 3b of the second semiconductor chip 3.

The third semiconductor chip 4 is rectangular and includes a fifth main surface 4a fixed on the fourth main surface 3b of the second semiconductor chip 3 and a sixth main surface 4b opposed to the fifth main surface 4a. The chip 4 includes third pads 24 (24c) along one side of the sixth main surface 4b. The chip 4 is displaced from right above the second semiconductor chip 3 only by a region corresponding to at least the second pads 23 (23c) such that the third pads 24 (24c) are prevented from being formed right above the second pads 23 (23c) but they are close to the second pads 23 (23c). The third pads 24 (24c) of the chip 4 and the third substrate-side pads 14 (14c) are bonded to each other through third bonding wires 17 (17c).

A sealing resin layer 5 is formed around the first, second and third semiconductor chips 2, 3 and 4.

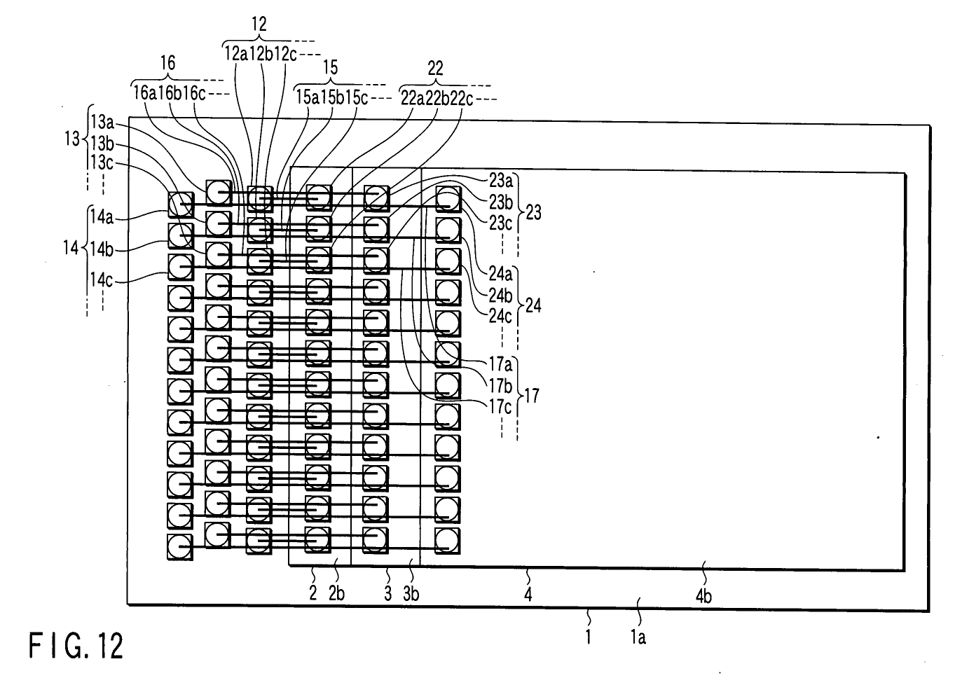

As shown in the plan view of FIG. 12, the first pads 22 (22a, 22b, 22c, . . . ) are arranged along one side of the first semiconductor chip 2. The second pads 23 (23a, 23b, 23c, . . . ) are arranged along one side of the second semiconductor chip 3 and adjacent to the first pads 22 (22a, 22b, 22c, . . . ). The third pads 24 (24a, 24b, 24c, . . . ) are arranged along one side of the third semiconductor chip 4 and adjacent to the second pads 23 (23a, 23b, 23c, . . . ). The first substrate-side pads 12 (12a, 12b, 12c, . . . ), second substrate-side pads 13 (13a, 13b, 13c, . . . ) and third substrate-side pads 14 (14a, 14b, 14c, . . . ) are arranged adjacent to each other. Since the other arrangements are the same as those of the semiconductor device shown in FIGS. 1 and 2, their descriptions are omitted.

According to the semiconductor device shown in FIGS. 11 and 12, the second semiconductor chip 3 is stacked on and slightly displaced from the first semiconductor chip 2, and the third semiconductor chip 4 is stacked on and slightly displaced from the second semiconductor chip 3. Space for keeping the level of a loop of the first, second and third bonding wires 15, 16 and 17 can be obtained. Any intermediate substrate or dummy chip is not required and accordingly the semiconductor device can be thinned.

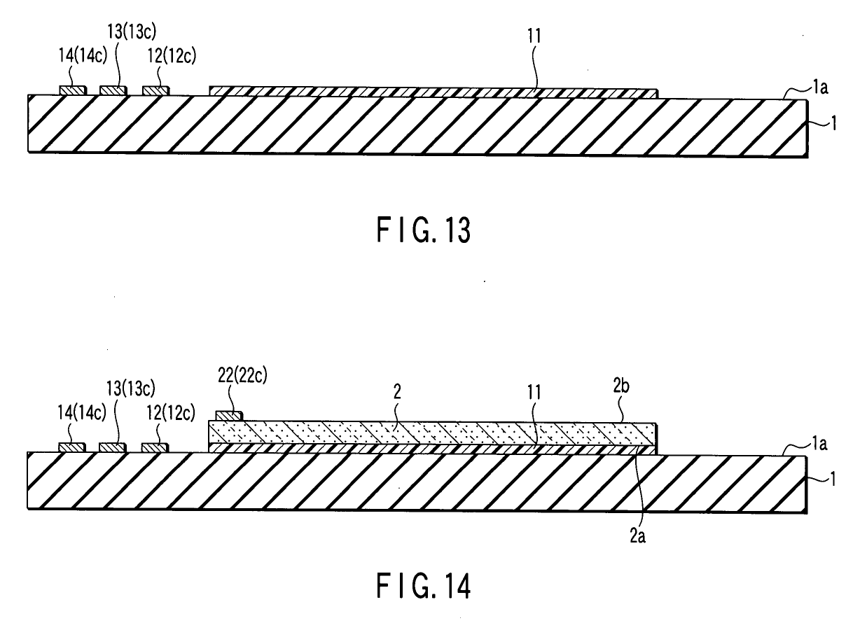

A method of manufacturing the semiconductor device according to the second embodiment will be described with reference to FIGS. 13 to 18.

Referring first to FIG. 13, a package substrate 1 having first, second and third substrate-side pads 12 (12c), 13 (13c) and 14 (14c) on the chip mounting surface la thereof is prepared. A first fixing resin layer 11 is formed on the chip mounting surface la of the package substrate 1. The first fixing resin layer 11 is shaped like a sheet in advance such that its shape almost corresponds to the outer shape of the first semiconductor chip 2, and it can be adhered directly onto the chip 2. The first fixing resin layer 11 can be formed by forming a resin layer on the chip mounting surface la and selectively punching the resin layer.

Then, a rectangular first semiconductor chip 2 having a first main surface 2a and a second main surface 2b opposed to the first main surface 2a is prepared. On the second main surface 2a, as shown in FIG. 12, first pads 22 (22a, 22b, 22c, . . . ) are arranged in line along one side of the first semiconductor chip 2. The first main surface 2a of the first semiconductor chip 2 is fixed on the first fixing resin layer 11 as shown in FIG. 14.

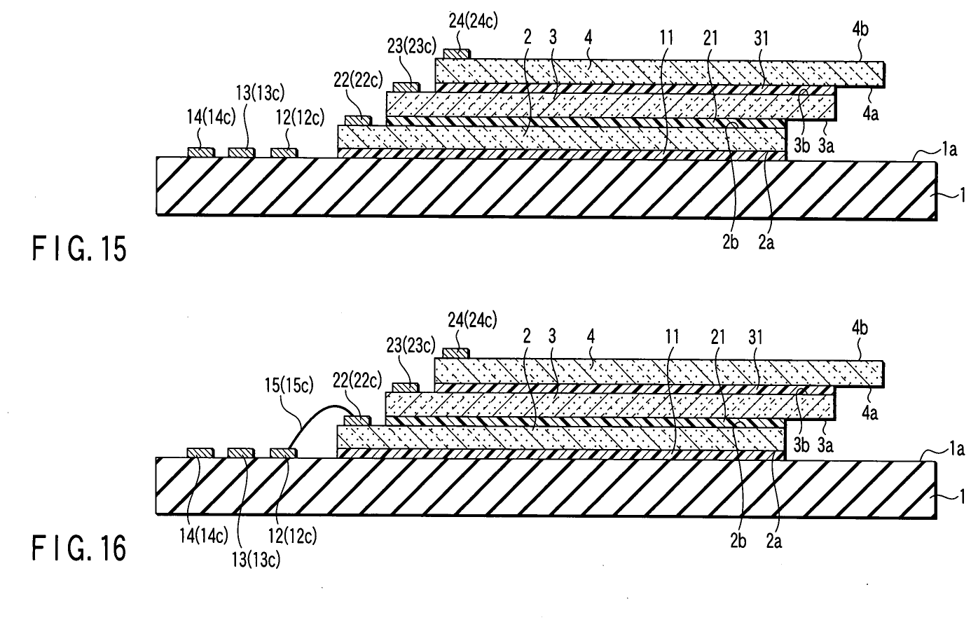

Then, a sheet-shaped second fixing resin layer 21 is formed on the second main surface 2b. A rectangular second semiconductor chip 3 having a third main surface 3a and a fourth main surface 3b opposed to the third main surface 3a is prepared. On the fourth main surface 3b, as shown in FIG. 12, second pads 23 (23a, 23b, 23c, . . . ) are arranged in line along one side of the second semiconductor chip 3. As shown in FIG. 15, the second semiconductor chip 3 is displaced from right above the first semiconductor chip 2 only by a region where the first pads 22 (22a, 22b, 22c, . . . ) are formed, and the third main surface 3a of the second semiconductor chip 3 is fixed on the second fixing resin layer 21.

Then, a sheet-shaped third fixing resin layer 31 is formed on the fourth main surface 3b. A rectangular third semiconductor chip 4 having a fifth main surface 4a and a sixth main surface 4b opposed to the fifth main surface 4a is prepared. On the sixth main surface 4b, as shown in FIG. 12, third pads 24 (24a, 24b, 24c, . . . ) are arranged in line along one side of the third semiconductor chip 4. As shown in FIG. 15, the third semiconductor chip 4 is displaced from right above the second semiconductor chip 3 only by a region where the second pads 23 (23a, 23b, 23c, . . . ) are formed, and the fifth main surface 4a of the third semiconductor chip 4 is fixed on the third fixing resin layer 31. Thus, the first, second and third semiconductor chips 2, 3 and 4 are stacked stepwise on the package substrate 1.

Referring then to FIG. 16, one end of the first bonding wire 15 (15c) is bonded to the first substrate-side pad 12 (12c), and the other end thereof is bonded to the first pad 22 (22c) by thermocompression bonding or ultrasonic bonding.

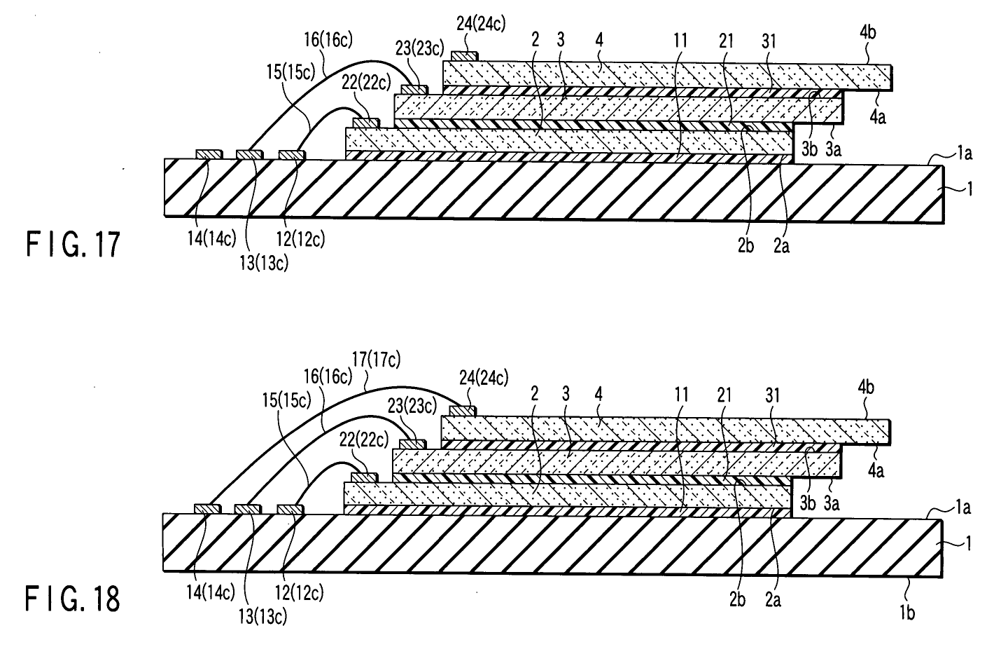

Similarly, as shown in FIG. 17, one end of the second bonding wire 16 (16c) is bonded to the second substrate-side pad 13 (13c), and the other end thereof is bonded to the second pad 23 (23c) by thermocompression bonding or ultrasonic bonding.

Similarly, as shown in FIG. 18, one end of the third bonding wire 17 (17c) is bonded to the third substrate-side pad 14 (14c), and the other end thereof is bonded to the third pad 24 (24c) by thermocompression bonding or ultrasonic bonding.

Finally, a sealing resin layer 5 is formed around the first, second and third semiconductor chips 2, 3 and 4, and an external connecting terminal 6 is provided on the external connecting surface 1b of the package substrate 1. Thus, the semiconductor device shown in FIGS. 11 and 12 is completed.

In the method of manufacturing the semiconductor device according to the second embodiment, the first, second and third semiconductor chips 2, 3 and 4 are stacked on the package substrate 1 stepwise and then the first, second and third substrate-side pads 12, 13 and 14 and the first, second and third pads 22, 23 and 24 are electrically connected to each other. Thus, an intermediate substrate or a dummy chip need not be inserted between the first, second and third semiconductor chips 2, 3 and 4. Space for arranging the first, second and third bonding wires 15, 16 and 17 can be kept. The semiconductor device can thus be thinned. In particular, after the first, second and third semiconductor chips 2, 3 and 4 are stacked, the first, second and third pads 22, 23 and 24 and the first, second and third substrate-side pads 12, 13 and 14 are electrically connected to each other at once. The steps for manufacturing the semiconductor device can be reduced.

### Other Embodiments

The present invention has been described as the first and second embodiments, but it is not limited to the descriptions or drawings of the embodiments. Various changes and modifications can be made to the present invention.

In the method of manufacturing the semiconductor device according to each of the first and second embodiments, the first, second and third bonding wires 15, 16 and 17 are raised from the package substrate 1 toward the first, second and third pads 22, 23 and 24 (reverse bonding). However, the bonding wires can be drawn down to the package substrate from the pads (forward bonding). In the semiconductor device according to each of the first and second embodiments, three semiconductor chips are stacked. However, two semiconductor chips or four or more semiconductor chips can be stacked. In the semiconductor device according to the second embodiment, for example, the first, second and third semiconductor chips 2′, 3′ and 4′ shown in FIG. 10 can be mounted. The arrangements of the first, second and third pads 22, 23 and 24 are not limited to those shown in FIGS. 2, 10 and 12. The pads can be arranged in various patterns.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a package substrate having a chip mounting surface and an external connecting surface opposed to the chip mounting surface, the chip mounting surface including at least a plurality of first substrate-side pads and a plurality of second substrate-side pads;
a rectangular first semiconductor chip having a first main surface fixed on the chip mounting surface and a second main surface opposed to the first main surface, the first semiconductor chip including a plurality of first pads arranged along one side of the second main surface;
a plurality of first bonding wires through which the first pads and the first substrate-side pads are bonded to each other;
a rectangular second semiconductor chip having a third main surface fixed on the second main surface and a fourth main surface opposed to the third main surface, the second semiconductor chip including a plurality of second pads arranged along one side of the fourth main surface and being displaced from above the first semiconductor chip to prevent the second pads from being arranged right above the first pads; and
a plurality of second bonding wires through which the second pads and the second substrate-side pads are bonded to each other.

2. The semiconductor device according to claim 1, wherein the first pads are arranged in line and the second pads are arranged in line.

3. The semiconductor device according to claim 1, wherein the first pads are arranged in two lines and the second pads are arranged in two lines.

4. The semiconductor device according to claim 1, wherein the one side of the fourth main surface of the second semiconductor chip is adjacent to the first pads.

5. The semiconductor device according to claim 1, wherein another side opposed to the one side of the fourth main surface of the second semiconductor chip is adjacent to the first pads.

6. The semiconductor device according to claim 1, wherein the chip mounting surface of the package substrate includes a plurality of third substrate-side pads, and further comprising:
a rectangular third semiconductor chip having a fifth main surface fixed on the fourth main surface of the second semiconductor chip and a sixth main surface opposed to the fifth main surface, the third semiconductor chip including a plurality of third pads arranged along one side of the sixth main surface and being displaced from above the second semiconductor chip to prevent the third pads from being arranged right above the second pads; and
a plurality of third bonding wires through which the third pads and the third substrate-side pads are bonded to each other.

7. The semiconductor device according to claim 6, wherein the third pads are arranged in line.

8. The semiconductor device according to claim 6, wherein the third pads are arranged in two lines.

9. The semiconductor device according to claim 6, wherein the one side of the sixth main surface of the third semiconductor chip is adjacent to the second pads.

10. The semiconductor device according to claim 6, wherein another side opposed to the one side of the sixth main surface of the third semiconductor chip is adjacent to the second pads.

11. A method of manufacturing a semiconductor device, comprising:
fixing a first main surface of a rectangular first semiconductor chip on a chip mounting surface of a package substrate, the package substrate having an external connecting surface opposed to the chip mounting surface, the chip mounting surface including at least a plurality of first substrate-side pads and a plurality of second substrate-side pads, the first semiconductor chip having a second main surface opposed to the first main surface and including a plurality of first pads arranged along one side of the second main surface;
fixing a third main surface of a rectangular second semiconductor chip on the second main surface of the first semiconductor chip, the second semiconductor chip having a fourth main surface opposed to the third main surface and including a plurality of second pads arranged along one side of the fourth main surface, the second semiconductor chip being displaced from above the first semiconductor chip to prevent the second pads from being arranged right above the first pads;
bonding the first pads and the first substrate-side pads to each other through first bonding wires; and
bonding the second pads and the second substrate-side pads to each other through second bonding wires.

12. The method according to claim 11, wherein one end of each of the first bonding wires is bonded to a corresponding one of the first substrate-side pads, and then the other end thereof is bonded to a corresponding one of the first pads.

13. The method according to claim 11, wherein one end of each of the second bonding wires is bonded to a corresponding one of the second substrate-side pads, and then the other end thereof is bonded to a corresponding one of the second pads.

14. The method according to claim 11, wherein the second semiconductor chip is so provided that the one side of the fourth main surface is adjacent to the first pads.

15. The method according to claim 11, wherein the second semiconductor chip is so provided that another side opposed to the one side of the fourth main surface is adjacent to the first pads.

16. The method according to claim 11, wherein the chip mounting surface of the package substrate includes a plurality of third substrate-side pads, and further comprising:
fixing a fifth main surface of a rectangular third semiconductor chip on the fourth main surface of the second semiconductor chip, the third semiconductor chip having a sixth main surface opposed to the fifth main surface and including a plurality of third pads arranged along one side of the sixth main surface, the third semiconductor chip being displaced from above the second semiconductor chip to prevent the third pads from being arranged right above the second pads; and
bonding the third pads and the third substrate-side pads to each other through a plurality of third bonding wires.

17. The method according to claim 16, wherein one end of each of the third bonding wires is bonded to a corresponding one of the third substrate-side pads, and then the other end thereof is bonded to a corresponding one of the third pads.

18. The method according to claim 16, wherein the third semiconductor chip is so provided that the one side of the sixth main surface is adjacent to the second pads.

19. The method according to claim 16, wherein the third semiconductor chip is so provided that another side opposed to the one side of the sixth main surface is adjacent to the second pads.
